(19) United States
(12) Patent Application Publication
(10) Pub. No.: US 2007/0102831 A1
(43) Pub. Date: May 10, 2007

(54) Device and method of manufacturing the same

(76) Inventors: Shuntaro Machida, Kokubunji (JP); Natsuki Yokoyama, Mitaka (JP); Yasushi Goto, Kokubunji (JP)

Correspondence Address: REED SMITH LLP, 3110 FAIRVIEW PARK DRIVE, SUITE 1400, FALLS CHURCH, VA, 22042, US

(21) Appl. No.: 10/583,862

(22) PCT Filed: Dec. 24, 2003
(86) PCT No.: PCT/JP03/16571

§ 371 Date: Jun. 21, 2006

(51) Int. Cl. H01L 21/66; H01L 23/28

(52) U.S. Cl. 257/787; 438/15

(57) ABSTRACT

The present invention has a object to enhance the yield and facilitate bonding in a device provided with micro-mechanical elements formed by a MEMS technique. According to the inveniton, when a first wafer having a plurality of areas in which micro-mechanical elements and pads are formed and a second wafer in which an aperture is formed are to be glued together, the aperture is shared by the pads in the plurality of areas. This makes it possible for individual chips, into which the wafer is cut out, to be bonded with a conventionally used wire bonder because a sufficient aperture is provided above the pads. Further according to the invention, at the step of dicing two glued wafers into individual chips, the two wafers are separately cut. This enables chipping of the wafers to be reduced and the yield at the dicing step to be enhanced.

### FIELD OF THE INVENTION

The present invention relates to a device which is sealed by using wafers and a method of manufacturing the same. More particularly, it is to provide, in technology known as MEMS (Micro-Electro-Mechanical System) for forming micro-mechanical elements by using an LSI manufacturing process, a sealing method suitable for manufacturing devices equipped with micro-mechanical elements and a most suitable dicing method for wafer-sealed devices.

### DESCRIPTION OF RELATED ART

The MEMS is a technology for fabricating micro-size mechanical elements on the wafer surface by using LSI manufacturing techniques, and those micro-mechanical elements are used as sensors for detecting pressure, acceleration and the like and switches for establishing electrical contact. Since such a micro-mechanical element has a movable part which moves when the element operates as a sensor or a switch, a device having micro-mechanical elements needs to have its movable part kept in a sealed cavity when it is to be packaged.

As a method to carry out packaging with the movable part kept in the sealed cavity, conventionally, after a semiconductor wafer in which micro-mechanical elements are fabricated is cut into individual chips, each chip is can-packaged. By this method, however, the micro-mechanical elements may be damaged by cut wastes generated in the processing of dicing the chips. On account of this problem, more recently a packaging method of gluing a wafer made of Si or glass onto a wafer in which micro-mechanical elements are formed has come to be adopted. In this method, after gluing the wafers together, the following contrivances are done according to the known art to establish electrical connection to pads formed over the wafer in which the micro-mechanical elements are formed. For instance, the JP-A-2003-517946 (hereinafter referred as Patent Document 1; International Application number PCT/EP00/12672) discloses a method by which a base object and a protective object are joined together to provide a composite object, and an electrical connecting part formed in a hollow in the composite object is partially exposed by cutting a slit into the material on the surface of the composite object.

Also, JP-A-2002-246489 (hereinafter referred as Patent Document 2) discloses a method by which, after a hole is bored in the lid wafer to secure a necessary space for electrical connection, a wafer in which semiconductor elements are formed and the lid wafer are joined together.

Further, JP-A-2001-144117 (hereinafter referred as Patent Document 3) discloses a method by which, in order to allow access to contact pads of the substrate wafer, a plurality of holes for a test probe and bond wires are bored into the cap wafer before the substrate wafer and the cap wafer are stuck together.

### DISCLOSURE OF THE INVENTION

According to Patent Document 1, as apertures are bored after the wafer having no aperture and the wafer in which the micro-mechanical elements are formed are glued together, the upper portion of the electrical connecting part has to be cut off. As a consequence, the dicer used for the cutting may come into contact with the electrical connecting part and thereby damage the electrical connecting part itself.

According to Patent Document 2, since apertures are bored into the lid wafer in advance and gluing together is done after that, damage to the electrical connecting part can be averted. According to Patent Document 2, however, because of the presence of the lid wafer above the electrical connector when the individual chips are diced, some contrivance should be made in bonding to prevent the wires from coming into contact with the lid wafer when the electrical connector is wire-bonded.

According to Patent Document 3, since the substrate wafer and the cap wafer are glued together after the apertures are bored into the cap wafer as in the case of Patent Document 2, particles can be prevented from sticking to the contact pads. According to Patent Document 3, however, since the apertures are formed only above the contact pads, the thickness of the cap wafer poses an obstacle at the subsequent wire bonding step, and a wire bonder which permits bonding even of a high aspect ratio (the thickness of the cap wafer/the width of the apertures) is required.

Furthermore, the present inventors became aware of the need to take account of the following point in dicing individual chips after gluing together the wafer in which the micro-mechanical elements are formed and the wafer to seal the micro-mechanical elements. Thus, when attempting to collectively dice the plurality of glued wafers with a dicer, trying to cut the lower wafer following the cutting of the upper wafer may conceivably cause the blade of the dicer cutting the lower wafer to come into contact with the upper wafer. This would invite cracking from the cut face of the upper wafer or so-called chipping, which is a phenomenon of the cut face being chipped off, and the yield would fall. Also, where the upper wafer and the lower wafer are formed of different materials, the resistance to the blade of the dicer cutting the wafers differs between the upper wafer and the lower wafer, and this might invite deviation of the blade from the cut face to further chip the upper wafer and a drop in yield.

The present invention has been attempted in view of the problems noted above, and an object of the invention is to provide a device which makes possible, at the step of wire-bonding the chips cut out by dicing, to bond them with a wire bonder conventionally used for LSI manufacturing, and a method of manufacturing the same. Further, another object of the invention is to provide a device to accomplish wafer-based packaging by gluing together a wafer in which micro-mechanical elements are formed and a wafer which is to seal the micro-mechanical elements, the device being capable of enhancing the yield and a method of manufacturing the same.

The above-stated and other objects and novel features of this invention will become apparent from the description in this specification and drawings appended thereto.

An outline and advantages of typical aspects of the invention disclosed in the present application will be briefly described below.

Thus, it has a first wafer having a first area on which first micro-mechanical elements and a first pad are formed and a second area on which second micro-mechanical elements and a second pad are formed, and a second wafer in which an aperture for pads is bored, wherein the apertures are shared by a first pad and a second pad. This facilitates wire bonding when the first wafer is cut into individual chips, because a sufficient aperture is provided above the first pad and the second pad.

Further, in the process of dicing the glued first and the second wafers into individual chips, a step of cutting the first wafer along the first scribe area, and a step of cutting the second wafer along the second scribe area are provided to separately cut the first wafer and the second wafer, which enables chipping of the wafers to be reduced and the yield of the dicing process to be enhanced.

### BRIEF DESCRIPTION OF THE SEVERAL VIEWS OF THE DRAWINGS

FIG. 1 shows an overall view of a wafer having micro-mechanical elements and a wafer having apertures.

FIG. 2 show an enlarged view of the wafer having micro-mechanical elements and an enlarged view of the wafer having apertures.

FIG. 3 shows a state in which the wafer having micro-mechanical elements and the wafer having apertures are glued together.

FIG. 4 shows an enlarged view of apertures when the wafer having micro-mechanical elements and the wafer having apertures are glued together.

FIG. 5 shows a state in which the glued wafers are packaged and bonded with wires.

FIG. 6 shows a state in which a transistor area and a wiring area are formed in two areas adjoining each other with a scribe area in-between over the substrate wafer.

FIG. 7 shows an enlarged view of a state in which the transistor area and the wiring area are formed over the substrate wafer.

FIG. 8 show steps of forming micro-mechanical elements over the substrate wafer.

FIG. 9 show a state in which micro-mechanical elements and pads are formed in two areas adjoining each other with the scribe area in-between over the substrate wafer.

FIG. 10 show a state in which the wafer in which micro-mechanical elements are formed and the wafer having apertures are glued together.

FIG. 11 show a state in which the wafer having apertures is cut.

FIG. 12 show a state in which the wafer in which micro-mechanical elements are formed is cut.

FIG. 13 show process flows of cutting the wafers.

FIG. 14 shows a state in which a chip is packaged and the pads over the chip and the package are bonded to each other.

FIG. 15 shows a schematic system block diagram of a sensor using the micro-mechanical elements according to this embodiment.

FIG. 16 show an enlarged view of the wafer having micro-mechanical elements and an enlarged view of the wafer having apertures in Embodiment 2.

FIG. 17 shows a state in which the wafer having micro-mechanical element and the wafer having apertures are glued together in Embodiment 2.

FIG. 18 show how apertures are shared by a plurality of adjoining areas in Embodiment 3.

FIG. 19 show how apertures are shared by a plurality of adjoining areas in Embodiment 4.

### DETAILED DESCRIPTION OF THE INVENTION

### Embodiment 1

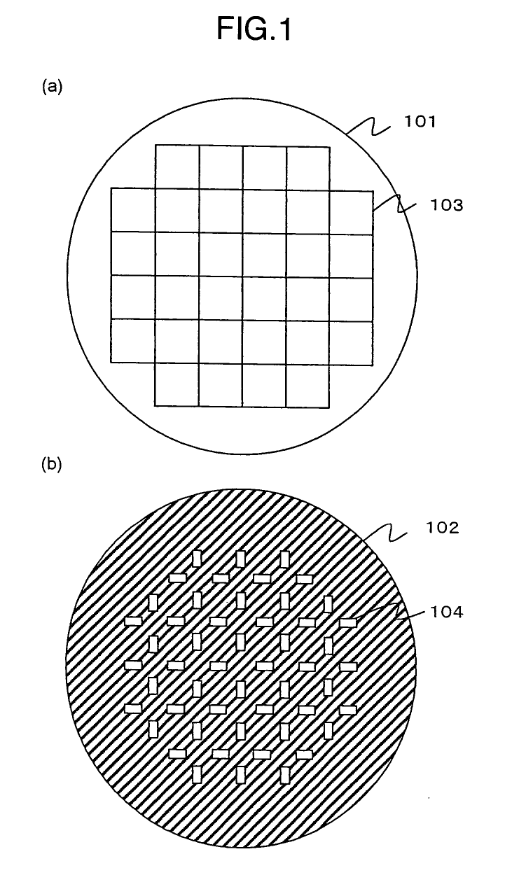

FIG. 1(a) shows a top view of a wafer 101 in which micro-mechanical elements are formed by an LSI manufacturing process known as MEMS, and FIG. 1(b) shows a top view of a wafer 102 to seal the micro-mechanical elements formed in the wafer 101. In the present application, MEMS refers to a technique by which micro-size mechanical elements are formed by the LSI manufacturing process and structures formed by that technique are referred to as micro-mechanical elements. Scribe areas 103 are formed in the wafer 101, and a micro-mechanical element, formed by the MEMS technique to be described afterwards, and a pad are formed in each of a plurality of areas surrounded by the scribe areas. As the wafer 102 to seal the micro-mechanical elements, a borosilicate glass wafer of 300 μm in thickness or a silicon wafer of 600 μm in thickness is used, though the choice is not limited to them. The wafer 102 to seal the micro-mechanical elements is provided with apertures 104 for bonding the pads, formed in the wafer 101. The apertures 104 are bored by blasting or otherwise where the wafer 102 is a glass wafer or by a dry etching method known as the Bosch process, for instance, where it is a silicon wafer.

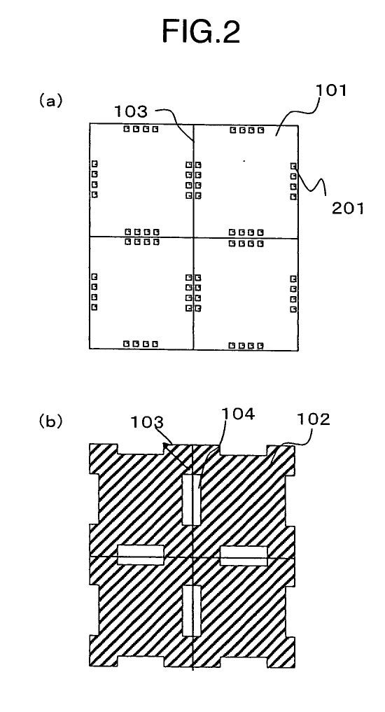

FIG. 2(a) shows an enlarged view of the wafer 101 in which micro-mechanical elements and pad are formed, and FIG. 2(b), an enlarged view of the wafer 102 having apertures. Each of these drawings shows a top view of four adjoining areas out of the areas surrounded by scribe areas. Each of the areas of the wafer 101 shown in FIG. 2(a) is separated from others by the scribe areas 103, and each of the scribe areas is positioned between pads 201 formed in the areas. Each of the areas of the wafer 102 shown in FIG. 2(b) is separated from others by the scribe areas 103 when glued together with the wafer 101 shown in FIG. 2(a), and each scribe area crosses the apertures 104.

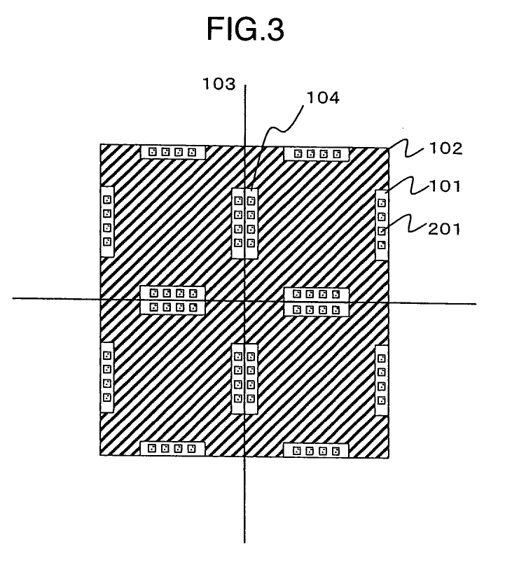

FIG. 3 shows a state in which the wafer 101 shown in FIG. 2(a) and the wafer 102 shown in FIG. 2(b) are glued together. As shown in the drawing, the wafer 101 provided with micro-mechanical elements formed in a plurality of areas surrounded by scribe areas and the wafer 102 which seals the micro-mechanical elements with a certain space over the micro-mechanical elements are glued together. The pads 201 formed in the plurality of areas in the wafer 101 are commonly opened by the apertures 104 bored in the wafer 102.

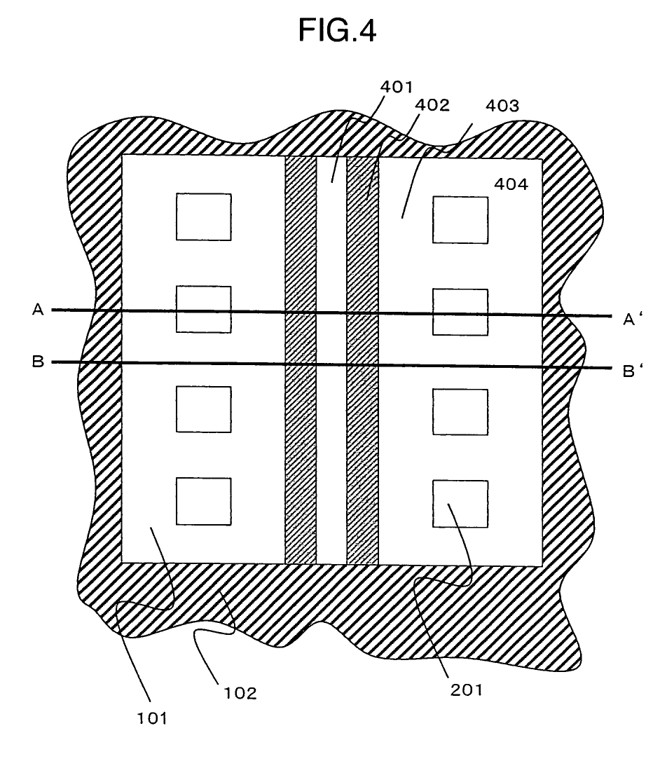

FIG. 4 shows an enlarged view of a state in which two areas opposed to each other with a scribe area in-between of the wafer 101, out of the glued wafers, and pads formed in the two areas are opened by apertures in the wafer 102. The width of a scribe area 401 of the wafer 101 is substantially equal to the blade width of the dicer to cut the wafer. The width of the scribe area here is supposed to be 50 to 100 microns, though it is not particularly limited to this range. The two areas having the scribe area between them are provided with areas 402, which adjoin the scribe area and are about as wide as the scribe area. By disposing these areas, allowances can be provided against wafer chipping which might occur when the wafer 101 is cut. Further, areas 403 of approximately the same width as the pads are provided between these areas 402 and the pads 201 for bonding. Allowances can be thereby provided, when the areas surrounded by scribe areas are cut into individual chips, between the edges of chips and the pads. The pad width here is supposed to be 50 to 100 microns, though it is not particularly limited to this range. Further, areas 404 of approximately the same width as the pads 201 are disposed between the pads 201 and edges of apertures. Allowances can be thereby provided between the pads 201 and the wafer 102 having the apertures.

By gluing together in this way the wafer 102 in which apertures are bored in advance and the wafer 101 to seal the micro-mechanical elements, the pads 201 can be opened without having to cut off their top parts, and cutting wastes generated by the boring of apertures in the wafer 102 can be prevented from stocking to the pads. Also, as the apertures in the wafer 102 are shared through bonding pads disposed in the two adjacent areas over the wafer 101, the scribe areas formed in the wafer 101 can be seen from above through the apertures 104 of the wafer 102 when the wafers are glued together. As a result, it is made possible to perform dicing while looking at the scribe areas formed in the wafer 101 and thereby to enhance the yield.

Although the sizes of the areas around the scribe area were described in terms of comparison with the blade of the dicer with reference to FIG. 4, this width is not limited to what was described regarding this embodiment. Further, the number of the pads 201 disposed in the two areas having the scribe area between them is supposed to be four in FIG. 4, where the number of pads opened per aperture is supposed to be eight. However, obviously the embodiment is not limited to these numbers, but variations are possible according to different situations. Also the size of each aperture can be varied according to the number of pads.

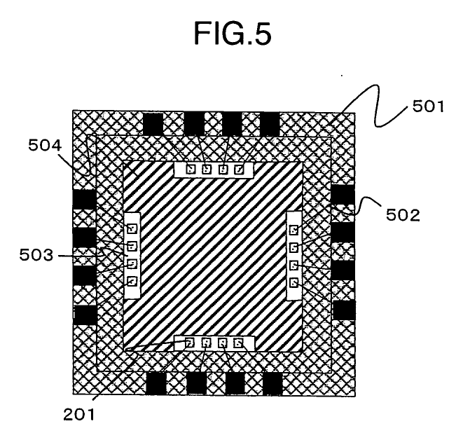

FIG. 5 shows the state of the package when the wafer 101 and the wafer 102 glued together are cut along the scribe area to be cut into individual chips, and the cut chips are mounted over a package 501 and bonded with wires 502. As illustrated in this drawing, there are areas in which no layer is stacked above the bonding pads 201, and these bonding pads and the package are bonded with the wires 502. Since apertures which commonly open the pads formed in two adjacent areas are disposed in the wafer 102 in this way, areas not covered by a layer 504 to seal the micro-mechanical elements can be secured on the outermost circumferences of the chips by merely dicing the chips. As a result, wire bonding of the pads 201 is enabled to be accomplished with a wire bonder conventionally used in LSI manufacturing.

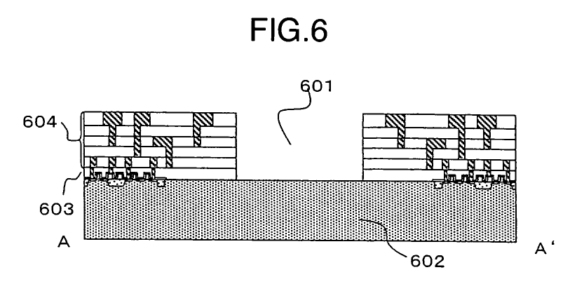

It has been described by way of top views how the wafer in which micro-mechanical elements are formed and the wafer in which apertures are bored, after they are glued together, are diced into individual chips and packaged. Hereafter, the process from the step of forming micro-mechanical elements in the wafer 101 to the step of sealing the wafer 101 and the wafer 102, cutting them into individual chips and packaging them will be explained with reference to FIG. 6 through FIGS. 13, which show sectional views.

First, FIG. 6 shows an enlarged sectional view of two areas opposed to each other with the scribe area in-between of the wafer 101 in which micro-mechanical elements are formed. The sectional view A-A′ shown here is a plane resulting from the cutting of the aperture shown in FIG. 4 along A-A′. As shown in the drawing, transistor areas 603 and wiring areas 604 are formed over, having between them a scribe area 601, which is formed over the Si substrate 602 of a semiconductor wafer.

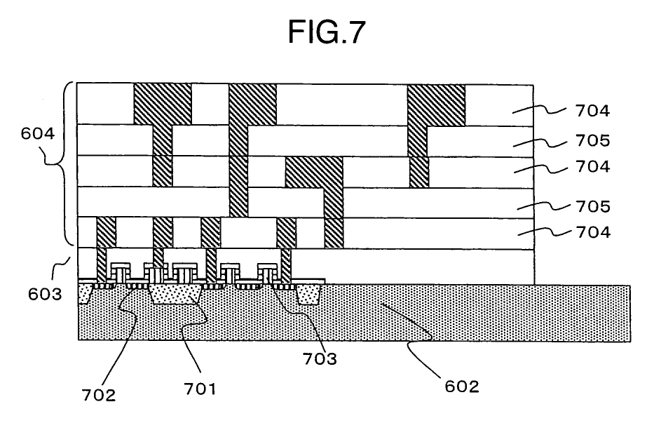

FIG. 7 shows an enlarged view of the transistor areas and the wiring areas shown in FIG. 6. Incidentally, FIG. 7 shows one each of the two kinds of areas opposed to each other having the scribe area between them. Within the Si substrate, there are formed an element separating area 701, a diffusion layer 702 and so forth. In the transistor area, a P-type MOS transistor and the gate electrode 703 of an N-type MOS transistor are formed. Above the transistor area in which the gate electrode is formed, there is disposed a wiring area for connecting circuits formed in the transistor area, micro-mechanical elements and pads. This wiring area comprises a total of five layers including alternately stacked wiring layers 704 formed of SiO₂ or the like and inter-layer contact layers 705 formed of Al, W or the like.

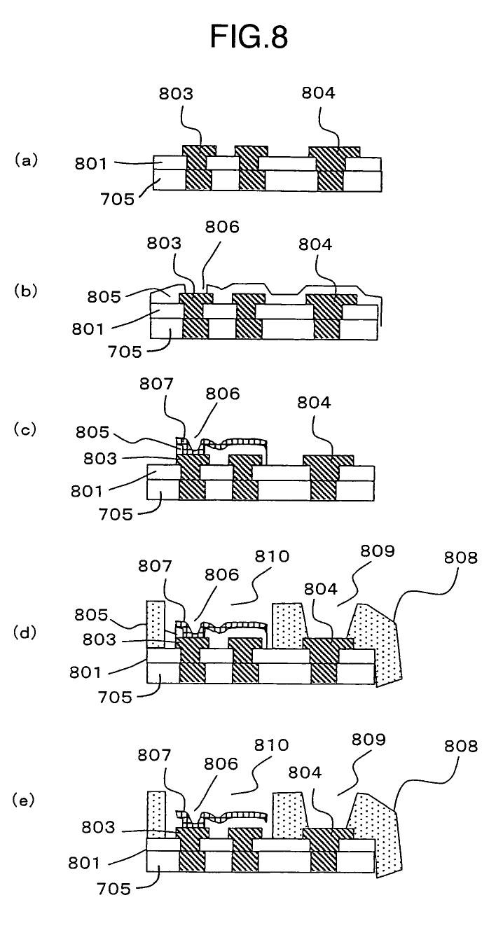

FIG. 8 show steps of forming micro-mechanical elements on the wiring area. Incidentally, the term micro-mechanical elements in this context refer to movable parts which perform the roles of sensors, switches and so forth with their moving portions and pads which are formed underneath the movable parts and have electrical relationships with the movable parts.

First, FIGS. 8(a) and (b) show how pads constituting micro-mechanical elements and pads bonded by wire bonding are formed. As shown in FIG. 8(a), after depositing a first laminate film 801 of a silicon oxide film 1 μm and a silicon nitride film 200 nm by plasma CVD over the top face of the wiring area, holes reaching an under-wiring 705 are formed in the first laminated layer 801 by a lithographic step and a dry etching step that follows. Next, aluminum is deposited to 1 μm over the wafer surface by sputtering, and pads 803 and 804 for electrical connection are formed by dry etching. The pad 803 becomes a pad to constitute a micro-mechanical element, and the pad 804 adjoining the scribe area 601, not shown, constitutes a pad for achieving bond wiring.

FIG. 8(b) shows how the pad 803 is bored. As shown in this drawing, a BPSG (Boro Phospho Silicate Glass) film 805 is deposited to 300 nm by CVD, and an aperture 806 is formed in the pad 803 by lithography.

Then, steps of forming the movable part of the micro-mechanical element are shown in FIG. 8(c) through FIG. 8(e). As shown in FIG. 8(c), a tungsten film is deposited to a 200 nm thickness by sputtering, and the tungsten film and the BPSG film 805 are machined into the pattern of the movable part by lithography and dry etching. This step results in embedding of tungsten into the aperture 806, and a movable part 807 of the micro-mechanical element and the pad 803 are connected.

FIG. 8(d) shows how a second laminate film 808 to separate the micro-mechanical element from the pad for bonding is formed. As shown in the drawing, first a silicon nitride film is deposited to 2 μm by plasma CVD. Next, an adhesive (of glass or polyimide material) for adhering the wafer to seal the micro-mechanical element to the wafer in which the micro-mechanical element is formed is applied. Then, the second laminate film 808 is formed, and an aperture 809 into the pad 804 and the aperture 806 around the movable part 807 are formed by lithography and dry etching.

Then, as shown in FIG. 8(e), the BPSG film 805 underneath the movable part 807 is wet-etched with an aqueous solution of hydrofluoric acid and dried to form the movable part. The drying uses a supercritical drying device to prevent the movable part of the micro-mechanical element from sticking to the under-layer.

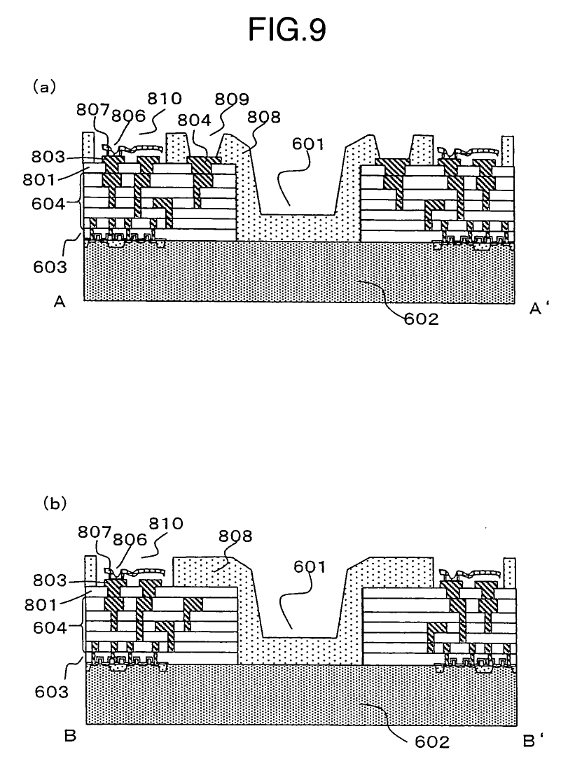

FIG. 9(a) shows a section in which the micro-mechanical element and the pad for bonding are formed on two areas with the scribe area in-between, and FIG. 9(b) shows a section in which a micro-mechanical element is formed but no pad is formed thereon. FIG. 9(a) shows a plane resulting from the cutting of the aperture shown in FIG. 4 along A-A′, and FIG. 9(b), a plane resulting from the cutting of the aperture shown in FIG. 4 along B-B′.

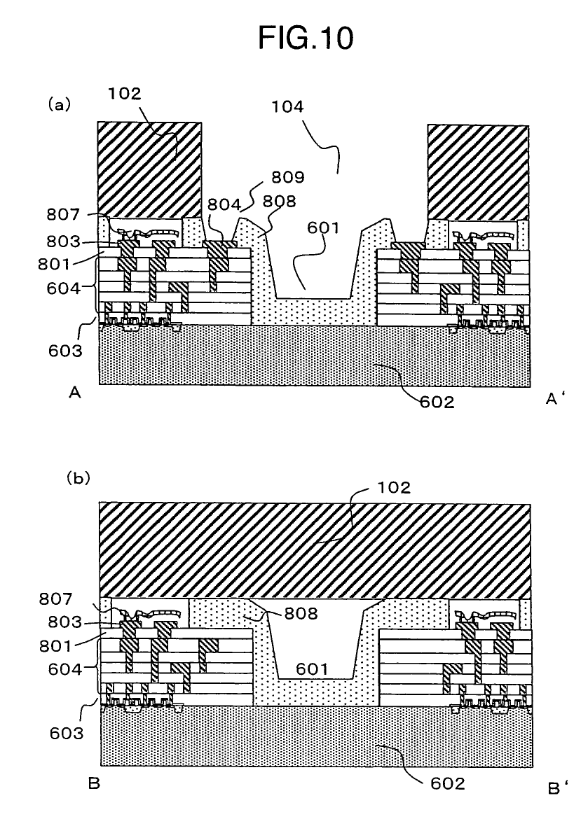

Then, FIG. 10 show the step of gluing together the wafer in which a micro-mechanical element is formed and the wafer in which an aperture is formed to seal the micro-mechanical element. FIG. 10(a) shows a section having both the micro-mechanical element and the bonding pad, and FIG. 10(b), a section having only the micro-mechanical element. The wafer in which the micro-mechanical element is formed and the wafer having the aperture are glued together in the following manner. As a first step, an alignment mark on the wafer in which the micro-mechanical element is formed and an alignment mark on the wafer for sealing are matched with each other with an aligner. Next, as a second step, heating and adhesion are carried out while applying pressure from above to the wafer having the aperture. Sufficiently airtight gluing can be achieved by heating at 400° C. where the adhesive is glass or at 300° C. where it is an organic polymer film such as polyimide.

By performing such an alignment at the time gluing, the wafers can be so glued together that the pad on the wafer in which the micro-mechanical element is formed and the aperture in the wafer for sealing exactly meet each other.

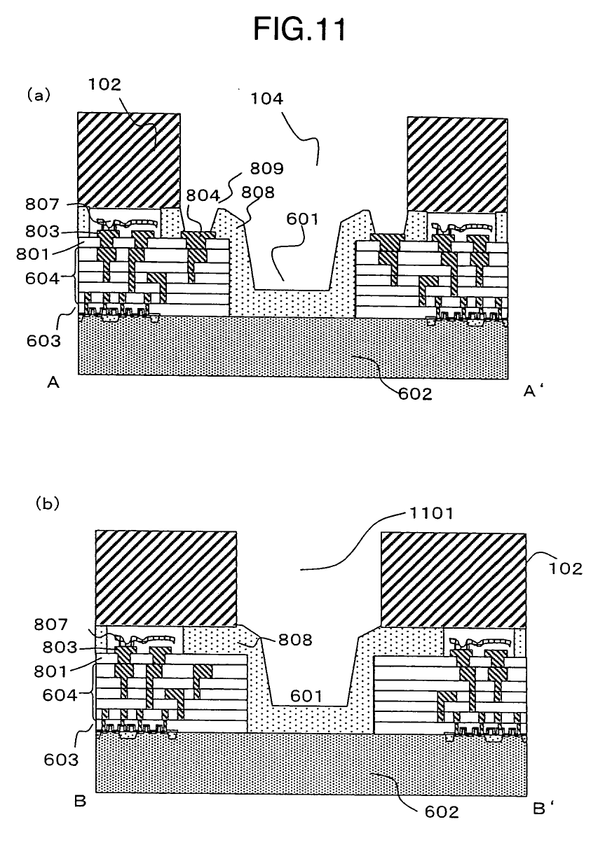

FIG. 11 show how the wafer for sealing the micro-mechanical element, out of the two wafers, is cut. The drawings show the process of formation of an aperture groove 1101 by cutting from above the scribe area of the wafer having an aperture with a dicer. By cutting the scribe area of the wafer having an aperture along the area surrounded by the scribe area, the layer sealing the micro-mechanical elements of individual chips can be cut apart. Since the wafer in which a micro-mechanical element is formed is not cut then, it is not cut apart into individual chips. Further, since there is an aperture over the scribe area of the wafer 101 in which a micro-mechanical element is formed, it is possible to dice the wafer 102 while looking at the scribe area formed in the wafer 101. For this reason, in dicing the wafer, there is no need to worry about any deviation between the cut faces of the wafer 101 and the wafer 102.

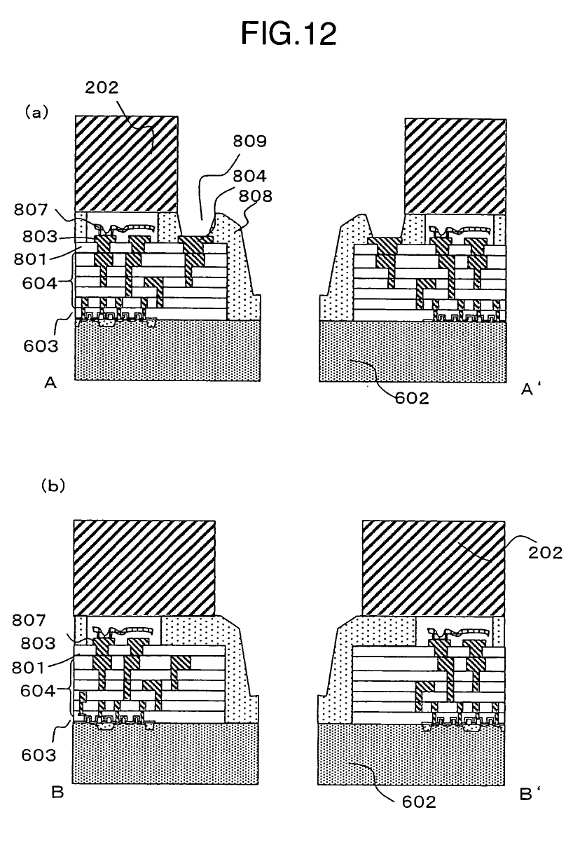

FIG. 12 show how glued wafers are cut from underneath. As shown in the drawings, only the wafer in which a micro-mechanical element is formed is cut from underneath of the glued wafers with a dicer along the scribe area. By dicing along the scribe area the area surrounded by the scribe area, the wafer is cut apart into individual chips.

By carrying out the dicing process in two stages by utilizing the groove portion in the scribe area, the thickness of the wafer to be cut in each stage can be made thinner and the load on the blade of the dicer can be made lighter as compared with the dising process of collectively dicing the glued wafers together. Also, the two-stage dicing can prevent the blade of the dicer from coming into contact with the already cut wafer and thereby help reduce the chipping of the wafer. Further, as the sealing wafer is cut along the groove portion in the scribe area of the wafer in which the micro-mechanical element is formed, the blade at the stage of cutting the sealing wafer does not come into contact with the wafer in which the micro-mechanical element is formed. Especially, where different materials are used, cutting of each wafer material can be accomplished independently of others. As a result, variations in the resistance to which the blade of the dicer to cut the wafer is exposed can be reduced, enabling the yield of the dicing process to be enhanced.

Incidentally, in the cutting of the glued wafers of this embodiment, the sealing wafer is cut at the first stage and the wafer in which the micro-mechanical element is formed is cut at the second stage. However, it is also possible to reduce the load on the blade of the dicer by inverting this cutting sequence, namely cutting the wafer 101 in which the micro-mechanical element is formed at the first stage and cutting the sealing wafer 102 at the second stage.

Further, in the cutting of the glued wafers of this embodiment, the sealing wafer 102 is cut from above at the first stage and the wafer 101 in which the micro-mechanical element is formed is cut from behind, namely from underneath at the second stage. However, it is also possible to do the cutting task at the second stage from the front side of the wafer in which a micro-mechanical element is formed, namely from above. In this case, since the rotary blade of the dicer has some deviation, it may damage the sealing wafer. This can be prevented by keeping the dicing width of the sealing wafer at the first stage greater than the dicing width of the wafer in which the micro-mechanical element is formed at the second stage.

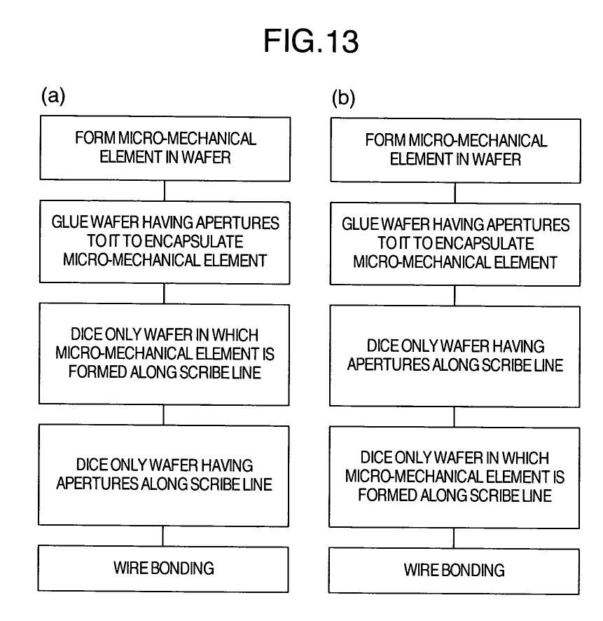

FIG. 13(a) and FIG. 13(b) show process flows putting together the steps described above. The difference between FIG. 13(a) and FIG. 13(b) consists in whether, at the dicing steps, the wafer to seal the micro-mechanical element is cut first or the wafer in which a micro-mechanical element is formed is cut first. As stated with reference to FIG. 11 and FIG. 12, irrespective of which wafer is cut first, the load on the dicer can be less than that of the case where the glued wafers are cut together. Also, chipping of the wafers can be prevented, enabling the yield of the dicing process to be enhanced.

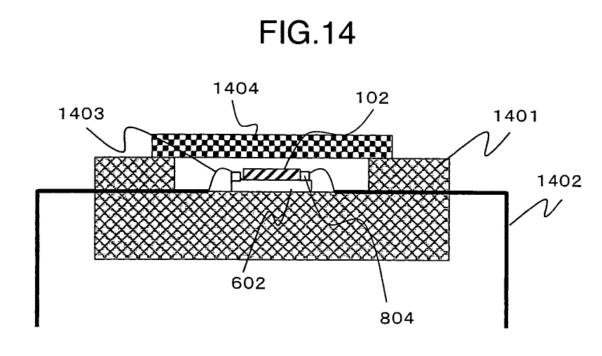

FIG. 14 shows a device in which a cut-apart chip is packaged. In FIG. 14, the bonding pads 804 on the chip provided with a micro-mechanical element and a lead 1402 of a ceramic DIP package 1401, for instance, are bonded with a wire 1403, followed by joining together of the package and a cap 1404. In this embodiment, over the wafer in which a micro-mechanical element is formed, the bonding pads formed in two adjoining areas are commonly opened by an aperture of the wafer having apertures. As a result, by merely dicing the area surrounded by the scribe area, an area not covered by the sealing layer 504 can be secured on the outermost circumference of the cut-out chip, and wire bonding to the pad 804 can be accomplished with a wire bonder conventionally used in LSI manufacturing.

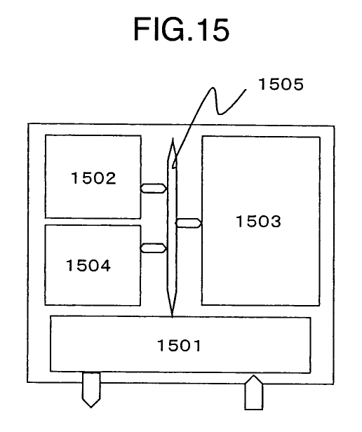

FIG. 15 shows a system block diagram of a sensor using a chip with the micro-mechanical elements according to this embodiment. In the diagram, an external I/O 1501 for inputting and outputting between the system and the outside, a MEMS unit 1502 provided ona chip with a micro-mechanical element serving as a sensor, a signal processing logic circuit 1503 which computes measurements from the chip and a memory 1504 which stores compensatory values and the like for calibrating the measurements are shown. Power among others is inputted to the external I/O, and this power is supplied to each block via a bus 1505. When the system is to serve as a sensor, the sensor on the chip 1502 measures with its micro-mechanical element variations in capacitance and resistance. These measurements are computed by the signal processing circuit via the bus 1505 connected to the chip, converted into values of acceleration, temperature and so forth, and outputted outside the sensor system via the external I/O. Either all the blocks of the system shown in the drawing may be formed on a single chip, or each block may be formed over an individual chip to be mounted on a board.

### Embodiment 2

While Embodiment 1 described above was a case in which two adjoining areas share a single aperture, in Embodiment 2 four adjoining areas share a single aperture. Incidentally, regarding this embodiment, description of the step of forming a transistor area, a wiring area, a micro-mechanical element and a pad over a wafer, a step of gluing together a wafer in which a micro-mechanical element is formed and a wafer having an aperture, a step of dicing them along a scribe area and a step of bonding individual chips will be dispensed with.

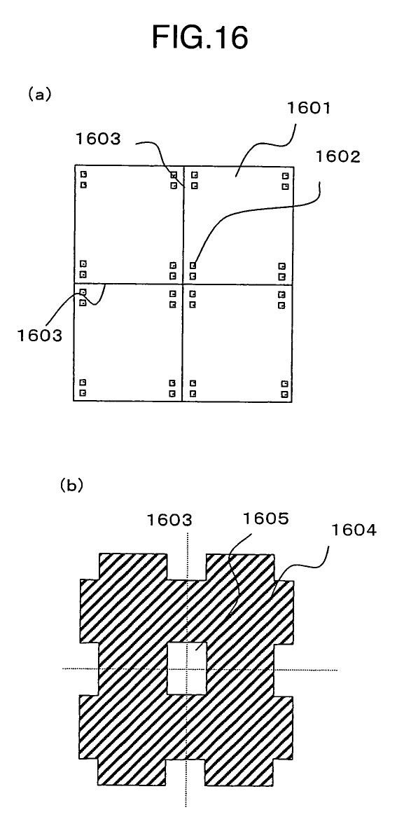

FIG. 16(a) shows a top view of four adjoining areas 1601, out of the areas surrounded by a scribe area in a wafer in which a micro-mechanical element is formed. Pads 1602 for electrical connection are arranged on the periphery of each area. In this embodiment, the pads formed in the four adjoining areas are arranged in the corners of the areas. Scribe areas 1603 separating these areas are placed between pads formed in the areas surrounded by the scribe areas.

FIG. 16(b) shows a top view of a wafer 1604 which seals a micro-mechanical element formed over the wafer of FIG. 16(a) and has an aperture. The sealing wafer 1604 is provided with an aperture 1605 shared with the electrically connecting pads 1602 of the adjoining four-chips. Each area of the wafer 1604 shown in FIG. 16(b) is separated, when glued together with the wafer 1601 shown in FIG. 16(a), by the scribe areas 1603, and each scribe area crosses the aperture 1605.

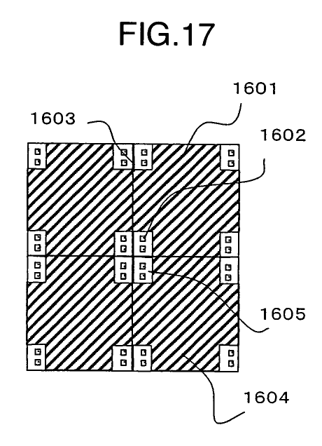

FIG. 17 shows a state in which the wafer having micro-mechanical elements and the wafer having the aperture are glued together. As shown in this drawing, the wafer 1601 provided with micro-mechanical elements formed in a plurality of areas surrounded by the scribe areas 1603 and the wafer 1604 to seal the micro-mechanical elements with a prescribed space above the micro-mechanical elements are glued together. The pads 1602 formed in the four adjoining areas of the wafer provided with micro-mechanical elements are commonly opened by the aperture 1605 formed in the wafer 1604.

By gluing together in this way the wafer in which an aperture is formed in advance with a wafer in which micro-mechanical elements are formed to seal the micro-mechanical elements, the pads can be opened without having to cut off the part above the pads. This enables to prevent cutting waste generated by the boring of apertures in the wafer in which no apertures are opened previously from sticking to the pads. Further in this embodiment, it is made possible for four adjoining areas to share a single aperture by arranging the pads in the corners of areas surrounded by the scribe areas.

### Embodiment 3

Embodiment 1 and Embodiment 2 described that in a wafer in which micro-mechanical elements are formed, four apertures are bored in a single area which is surrounded by scribe areas and is to constitute a chip and each of the apertures is shared by the adjoining areas. However, there is no particular limitation to the number of apertures, which can be varied according to the number of pads provided in the chip.

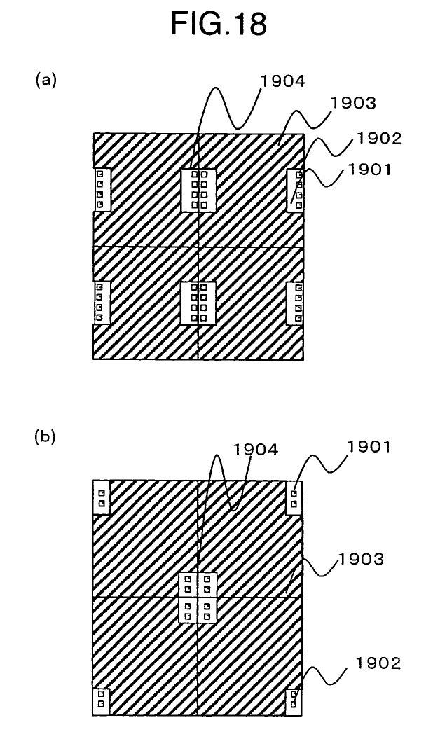

In this embodiment, as shown in FIG. 18, two apertures are bored per area surrounded by scribe areas, and each aperture is shared by adjacent areas. In FIG. 18(a), the apertures are arranged along the sides of areas to constitute chips, and in FIG. 18(b) the apertures are disposed in the corners of areas to constitute chips. FIG. 18(a) shows how pads 1902 formed in a wafer 1901 in which micro-mechanical elements are formed are opened by a wafer 1903 in which apertures 1904 are bored. As shown in the drawing, the apertures 1904 are arranged along the sides of areas which are to constitute chips and surrounded by scribe areas, and open the pads of two adjoining areas. FIG. 18(b) shows how the pads 1902 formed in the wafer 1901 in which micro-mechanical elements are formed are opened by the wafer 1903 in which the apertures 1904 are bored. The drawing shows how the apertures are arranged in the corners of areas which are to constitute chips and surrounded by the scribe areas, and a single aperture is shared by four adjoining areas. In both cases, the sharing of an aperture by adjoining areas enables the upper portions of the pads to be opened sufficiently. This makes it possible for individually cut-out chips to be bonded with a wire bonder conventionally used in LSI manufacturing.

### Embodiment 4

In this embodiment, each one aperture is bored in one of areas which is to constitute a chip and surrounded by scribe areas, in a wafer in which micro-mechanical elements are formed, and each aperture is shared by adjoining areas.

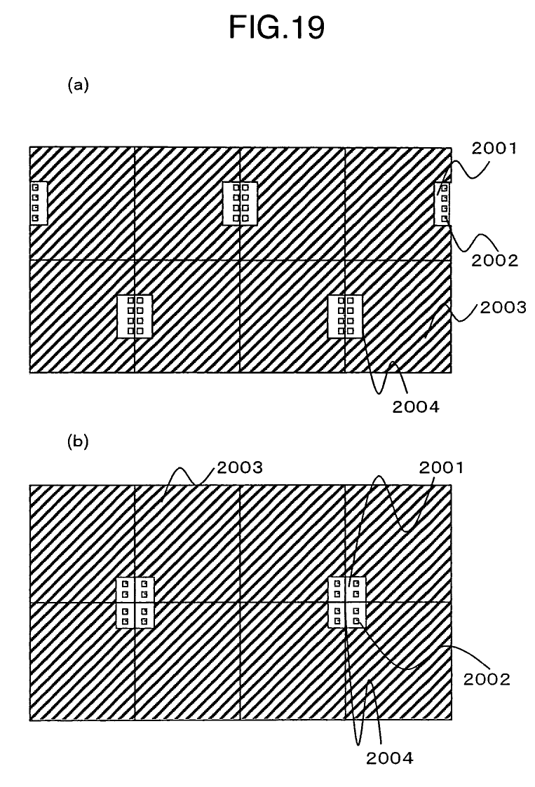

FIG. 19(a) shows how pads 2002 formed in a wafer 2001 in which micro-mechanical elements are formed are opened by a wafer 2003 in which apertures 2004 are bored. The apertures are arranged along one side of each area which is to constitute a chip and surrounded by scribe areas, and pads formed in areas which are to constitute two chips sharing this one side shares one aperture. FIG. 19(b) shows how the pads 2002 formed in the wafer 2001 in which micro-mechanical elements are formed are opened by the wafer 2003 in which the apertures 2004 are bored. These apertures are arranged in the corners of areas which are to constitute chips, and a single aperture is shared by four adjoining areas.

In this way, since a single aperture is shared by a plurality of areas which are to constitute chips in this embodiment, too, the upper portions of the pads can be opened sufficiently, making it possible to prevent the layer sealing micro-mechanical elements from coming into contact with any wire in the process of bonding.

Although the invention accomplished by the present inventor has been hitherto described in specific terms with reference to preferred embodiments thereof, the invention obviously is not limited to these embodiments, but can be modified in various manners without departing from the spirit of the invention and the scope of the appended claims.

For instance, while the foregoing description concerned methods of sealing, in a hollow by using wafers, micro-mechanical elements having movable parts formed by a MEMS technique, the invention can be used not only for micro-mechanical elements but also for other devices to perform sealing in a cavity by gluing wafers together.

In a wafer in which micro-mechanical elements are formed, with respect to the areas which are surrounded by scribe areas and to constitute chips, the cases in which a single aperture is provided for two adjoining areas or a single aperture is provided for four adjoining areas were also cited. Where a single aperture is to be provided for two adjoining areas, four apertures are provided per area surrounded by scribe areas in Embodiment 1; two apertures are provided per area in Embodiment 3 of FIG. 18(a); and one aperture is provided per area in Embodiment 4 of FIG. 19(a). Fruther, where a single aperture is to be provided for four adjoinging areas, four apertures are provided per area surrounded by scribe areas in Embodiment 2; two apertures are provided per area in Embodiment 3 of FIG. 18(b); and one aperture is provided per area in Embodiment 4 of FIG. 19(b). However, these can be obviously altered in many different ways according to the number of pads. For instance, it is also possible to provide three apertures per area which is to constitute a chip.

### INDUSTRIAL APPLICABILITY

The device provided with micro-mechanical elements formed by a MEMS technique can be applied to sealing and dicing of the sealed wafers in which micro-mechanical elements are formed.

1. A device having:
a first wafer having a first area and a second area opposed to each other with a first scribe area in-between, wherein a first mechanical element and a first pad are formed in said first area and a second mechanical element and a second pad are formed in said second area, and
a second wafer which selas said first mechanical element and said second mechanical element with a prescribed space over each of said first mechanical element and said second mechanical element formed in said first wafer, wherein:
said second wafer is provided with an aperture having a first side and a second side opposed to said first side, for exposing said first pad and said second pad, and
said aperture is so positioned that said first pad is placed between said first side and said first scribe area and said second pad is placed between said second side and said first scribe area.

2. The device according to claim 1, wherein:
said first wafer has a second scribe area and a third scribe area,
said aperture has a third side crossing said first side and said second side and a fourth side opposed to said third side,
the fourth side of said aperture is placed between said second scribe area, said first pad and said second pad, and
the third side of said aperture is arranged to be placed between said third scribe area, said first pad and said second pad.

3. The device according to claim 1, wherein:
said first wafer has:
a second scribe area,
a third area opposed to said first area with said second scribe area in-between, and
a fourth area opposed to said second area with said second scribe area in-between and opposed to said third area with said first scribe area in-between, wherein:
a third mechanical element and a third pad are formed in said third area,
a fourth mechanical element and a fourth pad are formed in said fourth area,
said aperture is so arranged as to expose said third pad and said fourth pad, and
said aperture is so arranged as to place said third pad between said first side and said first scribe area and to place said fourth pad between said second side and said first scribe area.

4. The device according to claim 3, wherein:
said aperture has a third side crossing said first side and said second side and a fourth side opposed to said third side,
said aperture is so arranged as to place said first and second pads between said third side and said second scribe area and to place said third and fourth pad between said fourth side and said second scribe area.

5. The device according to claim 1, wherein:
said first wafer further has a first laminate film formed between said first pad and said first mechanical element in said first area and a second laminate film formed between said second pad and said second mechanical element in said second area, and
said second wafer seals said first and second mechanical elements by being adhered to said first laminate film and said second laminate film.

6. The device according to claim 1, wherein:
said first wafer has a silicon substrate and a transistor formed over the silicon substrate.

7. The device according to claim 1, wherein:
said first mechanical element has a movable object having a movable part and a fifth pad formed underneath said movable object.

8. The device according to claim 1, wherein:
said first wafer further has second through fifth scribe areas,
said first area is surrounded by said first, second, third and fourth scribe areas, and
said second area is surrounded by said first, second, third and fifth scribe areas.

9. The device according to claim 8, wherein:
said first area is made a first chip by cutting said first, second, third and fourth scribe areas, and
said second area is made a second chip by cutting said first, second, third and fifth scribe areas.

10. The device according to claim 3, wherein:
said first wafer further has third through sixth scribe areas,
said first area is surrounded by said first, second, third and fourth scribe areas,
said second area is surrounded by said first, second, third and fifth scribe areas,
said third area is surrounded by said first, second, fourth and sixth scribe areas, and
said fourth area is surrounded by said first, second, fifth and sixth scribe areas.

11. The device according to claim 10, wherein:
said first area is made a first chip by cutting said first, second, third and fourth scribe areas,
said second area is made a second chip by cutting said first, second, third and fifth scribe areas,
said third area is made a third chip by cutting said first, second, fourth and sixth scribe areas, and
said fourth area is made a fourth chip by cutting said first, second, fifth and sixth scribe areas.

12-20. (canceled)

21. A device having:
a substrate having a first side, a second side opposed to said first side, a third side crossing said first and second sides, and a fourth side opposed to said third side,
a first pad and a second pad formed over said substrate,
a mechanical element formed over said substrate, and
a sealing layer which seals said mechanical element and has a first aperture opening said first pad and said second pad together, wherein:
said first aperture is so arranged as to place said first pad and said second pad between a fifth side of said first aperture and the first side of said substrate, and a sixth side which crosses said fifth side of said first aperture and comes into contact with the first side of said substrate is so arranged as to be placed between the third side of said substrate and said first pad and said second pad.

22. The device according to claim 21 wherein:
said first aperture is arranged in a corner formed between the first side and fourth side of said substrate.

23. The device according to claim 21 wherein:
said substrate further has a third pad and a fourth pad,
said sealing layer further has a second aperture opening said third pad and said fourth pad together, and
said second aperture is so arranged as to place third pad and said fourth pad between a seventh side of said second aperture and the second side of said substrate, and an eighth side which crosses said seventh side of said second aperture and comes into contact with the second side of said substrate is so arranged as to be placed between the fourth side of said substrate and said third and fourth pads.

24. The device according to claim 23 wherein:
said first aperture is arranged in a corner formed between the first side and fourth side of said substrate, and
said second aperture is arranged in a corner formed between the second side and third side of said substrate.

25. The device according to claim 23 wherein:
said substrate further has a fifth pad, a sixth pad, a seventh pad and a eighth pad,
said sealing layer further has a third aperture and a fourth aperture,
said third aperture is so arranged as to place said third pad between a ninth side of said third aperture and the third side of said substrate, a tenth side which crosses said ninth side of said third aperture and comes into contact with the third side of said substrate is placed between the second side of said substrate and said third pad,
said fourth aperture is so arranged as to place said fourth pad between an eleventh side of said fourth aperture and the fourth side of said substrate, and a twelfth side which crosses said eleventh side of said fourth aperture and comes into contact with the fourth side of said substrate is so arranged as to be placed between the first side of said substrate and said second pad.

26. The device according to claim 25, wherein:
said first aperture is arranged in a corner formed between the first side and fourth side of said substrate,
said second aperture is arranged in a corner formed between the second side and third side of said substrate,
said third aperture is arranged in a corner formed between the third side and first side of said substrate, and
said fourth aperture is arranged in a corner formed between the fourth side and second side of said substrate.
